(19) United States
(12) Patent Application Publication
(10) Pub. No.: US 2016/0308500 A1
(43) Pub. Date: Oct. 20, 2016

(54) BIAS-BOOSTING CIRCUIT WITH A MODIFIED WILSON CURRENT MIRROR CIRCUIT FOR RADIO FREQUENCY POWER AMPLIFIERS

(71) Applicant: Morfis Semiconductor, Inc., Irvine, CA (US)

(72) Inventors: Sifen Luo, Irvine, CA (US); Zhan Xu, Irvine, CA (US); Changli Chen, Irvine, CA (US); Haitao Li, Irvine, CA (US); Heng-chia Chang, Irvine, CA (US); Narisi Wang, Irvine, CA (US); Jung Ho Yoon, Irvine, CA (US)

(21) Appl. No.: 15/130,730

(22) Filed: Apr. 15, 2016

Related U.S. Application Data
(60) Provisional application No. 62/148,677, filed on Apr. 16, 2015.

(51) Int. Cl. H03F 3/213; H03F 1/02; H03F 3/195

(52) U.S. Cl. CPC H03F 3/213; H03F 3/195; H03F 1/0205; H03F 2200/451; H03F 2200/18

(57) ABSTRACT

A current mirror circuit for biasing a power amplifier includes a modified Wilson current mirror with a pair of first and second mirror transistors connected to a third transistor. The first mirror transistor is configured for operating in a saturation mode, with a gate voltage of the first mirror transistor being lower than a gate voltage of the power amplifier. The third transistor charges the power amplifier circuit during a positive half cycle of an input signal and the first mirror transistor discharges the power amplifier circuit during a negative half cycle of the input signal at different rates.

### CROSS-REFERENCE TO RELATED APPLICATIONS

This application relates to and claims the benefit of U.S. Provisional Application No. 62/148,677, filed Apr. 16, 2015 and entitled “BIAS-BOOSTING CIRCUIT WITH A MODIFIED WILSON CURRENT MIRROR CIRCUIT FOR RF POWER AMPLIFIER” the entirety of the disclosure of which is wholly incorporated by reference herein.

### STATEMENT RE: FEDERALLY SPONSORED RESEARCH/DEVELOPMENT

Not Applicable

### BACKGROUND

1. Technical Field

The present disclosure relates generally to radio frequency (RF) integrated circuits, and more particularly, to a bias-boosting circuit with a modified Wilson current mirror circuit for RF power amplifiers.

2. Related Art

Wireless communications systems find applications in numerous contexts involving information transfer over long and short distances alike, and there exists a wide range of modalities suited to meet the particular needs of each. Generally, wireless communications involve an RF carrier signal that is variously modulated to represent information, and the modulation, transmission, receipt, and demodulation of the signal conform to a set of standards for the coordination of the same.

Many different wireless communications technologies or air interfaces are known in the art, including GSM (Global System for Mobile communications), EDGE (Enhanced Data rates for GSM Evolution), UMTS (Universal Mobile Telecommunications System), and 4G LTE (Long Term Evolution). Additionally, local area data networking modalities such as Wireless LAN or WLAN (IEEE 802.11-series) are also widely utilized.

A fundamental component of any wireless communications system is the transceiver, that is, the combined transmitter and receiver circuitry. The transceiver encodes the data to a baseband signal and modulates it with an RF carrier signal. Upon receipt, the transceiver down-converts the RF signal, demodulates the baseband signal, and decodes the data represented by the baseband signal. An antenna connected to the transmitter converts the transmitted electrical signals to electromagnetic waves, as well as the received electromagnetic waves back to electrical signals. Typical transceivers do not generate sufficient power or have sufficient sensitivity in itself for reliable communications. Thus, additional conditioning of the RF signal is necessary. The circuitry between the transceiver and the antenna that provide such functionality is referred to as the front end module, which includes a power amplifier for increased transmission power, and/or a low noise amplifier for increased receive sensitivity.

In modern communications modalities/air interfaces mentioned above, the peak-to-average power ratio (PAPR) of the signals is high. For example, in a W-CDMA modulation scheme, the peak-to-average power ratio of the signals may be as high as 3.5 dB. In order to properly handle signals with such high peak-to-average power ratios, conventional designs utilize large transistors in the power amplifier circuitry. The biasing circuit for the power amplifier transistors is oftentimes a simple current mirror architecture, but there are several notable disadvantages. In particular, such power amplifiers may exhibit gain compression at high signal levels because of a voltage drop (I*R) across bipolar transistors, or because of a fixed voltage bias in field effect transistors.

Accordingly, there is a need in the art for an improved bias-boosting circuit that overcomes early gain compression in power amplifiers. There is also a need in the art for a bias-boosting circuit that extends the 1 dB compression point (P1 dB) to a higher power level while maintaining the quiescent current of the power amplifier transistor at a relatively low level.

### BRIEF SUMMARY

The present disclosure is directed to a modified Wilson current mirror circuit that provides a bias boost for power amplifier transistors. In accordance with various embodiments, a balance between power amplifier efficiency and linearity is maintained, while extending its 1 dB compression point. For the same output power, a relatively smaller transistor or amplifier circuit can be employed, leading to a reduced semiconductor die footprint as well as lower cost.

One embodiment of the present disclosure contemplates a radio frequency (RF) power amplifier circuit including an input receptive to a signal, and an output. The circuit may include an input matching network connected to the input, and an output matching network connected to the output. Additionally, there may be a power amplifier with a power amplifier input connected to the input matching network and a power amplifier output connected to the output matching network. The power amplifier circuit may further have a bias boosting circuit connected to the power amplifier input. The bias boosting circuit may be comprised of a modified Wilson current mirror with a pair of first and second mirror transistors connected to a third transistor. The first mirror transistor may be configured for operating in a saturation mode and a gate voltage of the first mirror transistor being lower than a gate voltage of the power amplifier. The third transistor may charge the power amplifier circuit during a positive half cycle of the signal and the first mirror transistor may discharge the power amplifier circuit during a negative half cycle of the signal at different rates.

Another embodiment of the present disclosure may be directed to a current mirror circuit for biasing a power amplifier. The circuit may include a modified Wilson current mirror with a pair of first and second mirror transistors connected to a third transistor. The first mirror transistor may be configured for operating in a saturation mode, with a gate voltage of the first mirror transistor being lower than a gate voltage of the power amplifier. The third transistor may charge the power amplifier circuit during a positive half cycle of an input signal and the first mirror transistor may discharge the power amplifier circuit during a negative half cycle of the input signal at different rates.

Still another embodiment of the present disclosure may be directed to a modified Wilson current mirror circuit for biasing a power amplifier. There may be a pair of first and second mirror transistors each with a gate, a drain, and a source. The gate of the first mirror transistor may be connected to the gate of the second mirror transistor. There may also be a third transistor with a gate, a drain, and a source. The modified Wilson current mirror circuit may further include a first resistor connected to the source of the third transistor, a second resistor connected to the drain of the first mirror transistor and the first resistor, and a third resistor connected to the source of the third transistor and the gates of both the first and second mirror transistors. A common node may be defined at a junction between the first resistor and the second resistor. The circuit may further incorporate a bias boost control resistor that is connected to the common node and connectible to the power amplifier.

The present invention will be best understood by reference to the following detailed description when read in conjunction with the accompanying drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic diagram illustrating an exemplary power amplifier circuit with a first embodiment of a modified Wilson current mirror circuit in accordance with one embodiment of the present disclosure;

FIG. 2 is a schematic diagram illustrating the power amplifier circuit with a second embodiment of a modified Wilson current mirror circuit;

FIG. 3 plots a simulated gain curve as a function of output power for the power amplifier circuits of FIGS. 1 and 2 incorporating the modified Wilson current mirror circuit as contemplated in the present disclosure in comparison to a gain curve of a simple current mirror circuit;

FIG. 4 plots simulated AM-PM characteristics of the power amplifier circuits of FIGS. 1 and 2 incorporating the modified Wilson current mirror circuit in comparison to the AM-PM characteristics of a simple current mirror circuit.

### DETAILED DESCRIPTION

The detailed description set forth below in connection with the appended drawings is intended as a description of the several presently contemplated embodiments of a modified Wilson current mirror circuit for RF power amplifiers, and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

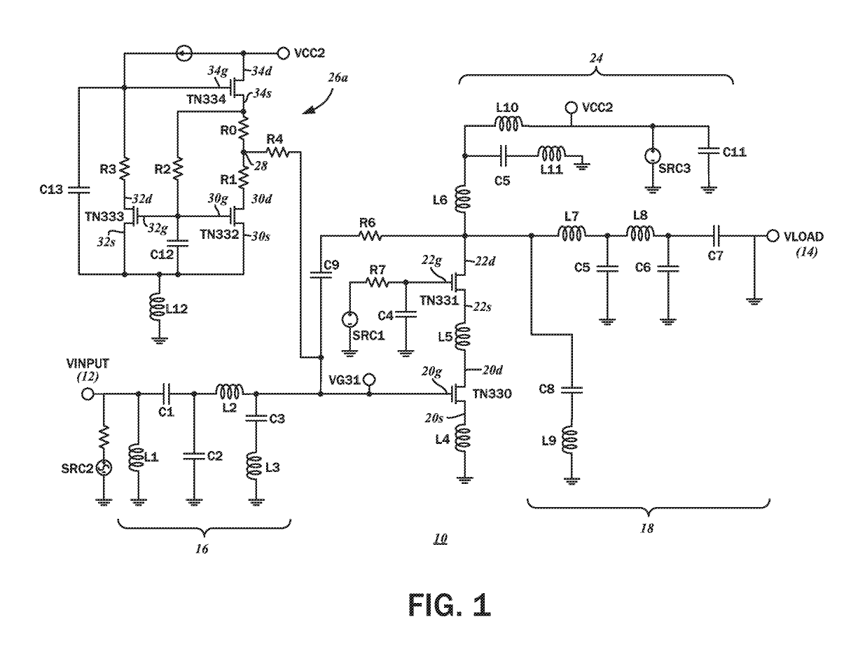

Referring to the schematic diagram of FIG. 1, one embodiment of the present disclosure is a power amplifier circuit 10 that has a stacked transistor configuration with a first power amplifier transistor TN330 and a second power amplifier transistor TN331. In a preferred, though optional embodiment, the first power amplifier transistor TN330 and the second power amplifier transistor TN331 are complementary metal oxide semiconductor (CMOS) field effect transistors (FETs) as particularly illustrated in the schematic diagram, though this is by way of example only and not of limitation. Amplifiers with three or more FETs stacked can be implemented in a similar way. With the first power amplifier transistor TN330 and the second power amplifier transistor TN331 being field effect transistors, each is understood to include a gate, a source, and a drain. To the extent other types of transistors are utilized, it will be understood that corresponding counterparts thereof are deemed to be encompassed within the scope of the present disclosure. For instance, if a bipolar junction transistor is utilized, references to the gate, source, and drain in the present disclosure are understood to correlate to the base, collector, and emitter, respectively.

The power amplifier circuit 10 is generally defined by a signal input 12 that is connectable to an RF signal source, along with a signal output 14 connectable to a load (such as an antenna). The signal input 12 is connected to an input matching network 16, an output of which is connected to the power amplifier transistors, more specifically, a gate 20g of the first power amplifier transistor TN330. The output from the power amplifier transistors is connected to an output matching network 18, which in turn is connected to the signal output 14. As will be recognized by those having ordinary skill in the art, the input matching network 16 and the output matching network 18 are comprised of various inductive, capacitive, and resistive elements to impedance match the power amplifier transistors to signal source components (in the case of the input matching network 16) and load components (in the case of the output matching network 18). The configuration and optimization of the input matching network 16 and the output matching 18 are within the purview of one of ordinary skill in the art, so for the sake of brevity, additional details thereof are omitted.

With the stacked transistor configuration, the signal from the input matching network 16 is connected to a gate 20g of the first power amplifier transistor TN330. The source 20s of the first power amplifier transistor TN330 is tied to ground, and a drain 20d of the first power amplifier transistor TN330 is connected to the second power amplifier transistor TN331, specifically the source 22s thereof. A drain 22d of the second power amplifier transistor TN331 is connected to the output matching network 18, as well as a biasing circuit 24 comprised of various capacitive and inductive components and a voltage supply SRC3.

The second power amplifier transistor TN331 is biased by the voltage supply SRC1, and thus the gate 22g of the second power amplifier transistor TN331 is connected thereto. In accordance with various embodiments of the present disclosure, a bias boost to the first power amplifier transistor TN330 is provided by a bias boosting circuit 26a, and output node of which is denoted as VG31. In addition to being connected to the input matching network 16, the gate 20g of the first power amplifier transistor TN330 is also connected to VG31, as shown.

A first embodiment of the bias boosting circuit 26a shown in FIG. 1 is a modified Wilson current mirror circuit, in which there are a pair of mirror transistors, e.g., a first mirror transistor TN332 and a second mirror transistor TN333 that are each connected to a third transistor TN334. This third transistor TN334, in turn is connected to a supply voltage VCC2. Per conventional practice, the gate 30g of the first mirror transistor TN332 and the gate 32g of the second mirror transistor TN333 are connected to the source 34s of the third transistor TN334. In addition, the source 34s of the third transistor TN334 is connected to the drain 30d of the first mirror transistor TN332. The drain 34d of the third transistor TN334 is connected to the voltage source VCC2, and the gate 34g of the same is connected to the drain 32d of the second mirror transistor TN333. The source 30s of the first mirror transistor TN332 and the source 32s of the second mirror transistor TN333 are connected to ground. Those having ordinary skill in the art will recognize the functionality and operational principles of the basic Wilson current mirror thus described, and so further details thereof will be omitted.

The various embodiments of the present disclosure contemplate a modified Wilson current mirror circuit that incorporates a first resistor R0, a second resistor R1, and a third resistor R2. The first resistor R0 is connected to the source 34s of the third transistor TN334, while the second resistor R1 is connected to the drain 30d of the first mirror transistor TN332. The first resistor R0 and the second resistor R1 are connected to each other and define a common node 28 at their junction. The third resistor R2 is connected to the source 34s of the third transistor TN334 and the gates 30g, 32g of the first and second mirror transistors TN332, TN333, respectively. A fourth resistor R3 is connected to the gate 34g of the third transistor TN334, the voltage source VCC2, and the drain 32d of the second mirror transistor TN333. The bias boosting circuit 26a, in combination with a bias control resistor R4, biases the first power amplifier transistor TN330, and is thus connected to the gate 20g of the same. The resistance value of the bias control resistor R4 is understood to control the bias boosting, while the third resistor R2 isolates the first power amplifier transistor TN330 from the first and second mirror transistors TN332, TN333.

According to one embodiment, the drain voltage of the first power amplifier transistor TN330 is based at a half of the supply voltage VCC2, or slightly higher so that there is equal voltage headroom for both of the stacked power amplifier transistors TN330 and TN331 close to the saturation point in large signal operation. With the first resistor R0, the second resistor R1, and the fourth resistor R3, the gate voltage of the first mirror transistor TN332 is increased for operation in saturation mode. Furthermore, the first resistor R0 and the second resistor R1 are configured such that the gate voltage of the first mirror transistor TN332 is lower than that of the first power amplifier transistor TN330 for proper biasing. In general, it is contemplated that the resistors R0 and R1 afford additional freedom to bias the power amplifier transistor and provide bias boosting.

As will be recognized by those having ordinary skill in the art, without the first resistor R0 and the second resistor R1, the drain voltage of the first mirror transistor TN332 would be equal to its gate voltage, as well as that of the first power amplifier transistor TN330. Due to channel-length modulation effect, the drain quiescent current in the first power amplifier transistor TN330 would be unacceptably high if the first power amplifier transistor TN330 and the first mirror transistor TN332 were operated in saturation mode with the same gate voltage. Furthermore, it would be undesirable for the first mirror transistor TN332 to be operated in the sub-threshold region as a biasing transistor because of the exponential relationship between current and voltage or temperature, which would otherwise be necessary for maintaining drain quiescent current in the first power amplifier transistor TN330 relatively low.

With the application of a large RF signal to the power amplifier, specifically at the gate 20g of the first power amplifier transistor TN330, the AC voltage at the drain terminal of the first transistor TN332 may be zero volts or almost zero volts during the negative half cycle of the RF signal. Under these circumstances, the first transistor TN332 may be turned off, and a current from the source 34s of the third transistor TN334 may charge the gate 20g of the first power amplifier transistor TN330. During the positive half cycle of the signal, the AC voltage at the source 34s of the third transistor TN334 may be higher than the voltage at the gate 34g, thereby turning off the third transistor TN334. The first mirror transistor TN332 accordingly discharges the gate 20g of the first power amplifier transistor TN330. Because of the high and low impedances at the drains 30d, 34d and sources 30s, 34s of the respective first mirror transistor TN332 and third transistor TN334, that is, the high impedance of the resistance R1 and the drain impedance of the first mirror transistor TN332, and the low impedance of the resistance R0 and the source impedance of the third transistor TN334, there is a difference in the charging and discharging rates. Along these lines, slight reductions in effective impedance at certain operating frequencies may be possible with capacitors connected in parallel with first and second resistors R0 and R1. Therefore, charging and discharging rates can be better controlled.

The different charging and discharging rates are understood to lead to charge accumulation at the gate 20g of the first power amplifier transistor TN330, along with an increase in the average DC voltage level as the input RF signal level increases. It will be appreciated that this effectively boosts the gate voltage of the first power amplifier transistor TN330, and extends the 1 dB compression point (P1 dB) of the power amplifier circuit 10. By so extending P1 dB efficiency and linearity of the power amplifier circuit 10 is improved. For a given output power, a relatively smaller transistor or amplifier may be utilized, with attendant decreases in die area and cost.

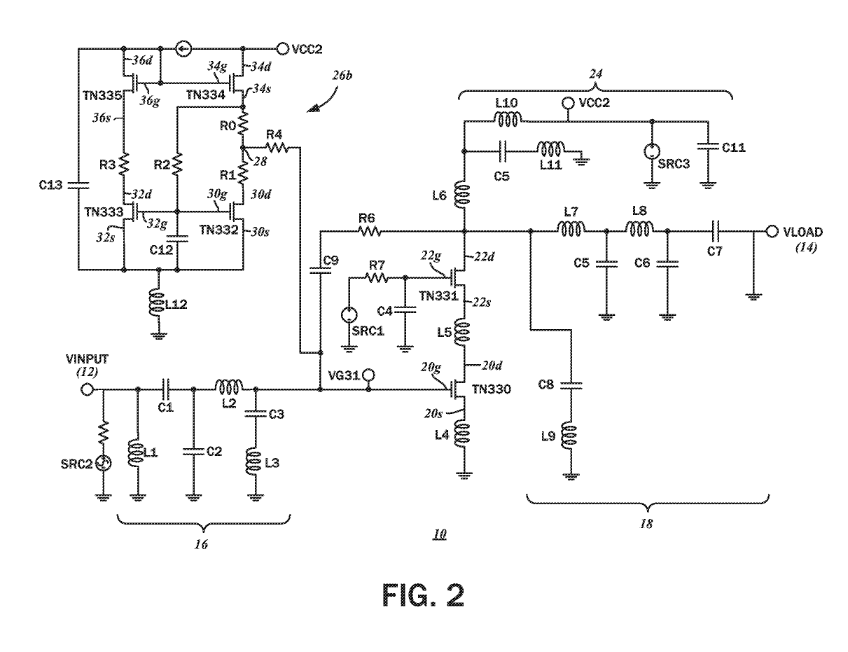

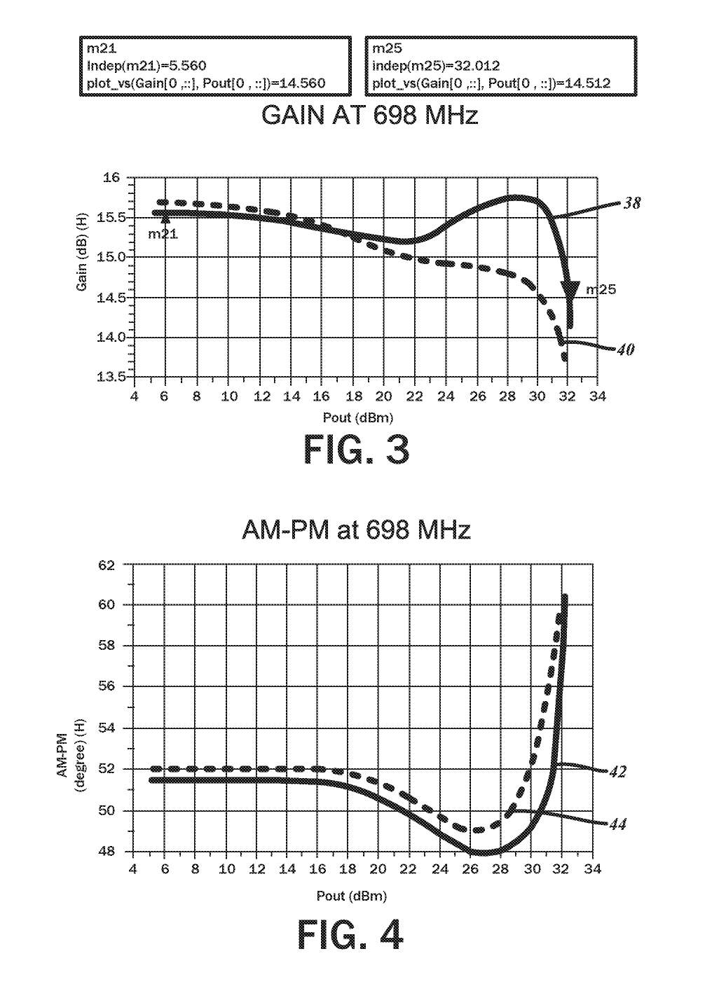

A second embodiment of the bias boosting circuit 26b is shown in FIG. 2, and is utilized in conjunction with the same power amplifier circuit 10 comprised of a stacked transistor configuration including a first power amplifier transistor TN330, a second power amplifier transistor TN331, an input matching network 16, an output matching network 18, and a biasing circuit 24. Like the first embodiment 26a shown in FIG. 1, the second embodiment of the bias boosting circuit 26b is a modified Wilson current mirror circuit but with the addition of a fourth transistor TN335. The second embodiment 26b likewise includes the first mirror transistor TN332 that is connected to the second mirror transistor TN333, that is, the respective gates 30g, 32g thereof are connected to each other, and further, to the third transistor TN334. The source 34s of the third transistor TN334 is connected to the drain 30d of the first mirror transistor TN332. The drain 34d of the third transistor TN334 is connected to the voltage source VCC2, and the gate 34g of the same is connected to the drain 36d of the fourth transistor TN335. The source 30s of the first mirror transistor TN332 and the source 32s of the second mirror transistor TN333 are connected to ground.

The fourth transistor TN335 is also in a mirror configuration with the third transistor TN334, as the gate 34g thereof is connected to the gate 36g of the fourth transistor TN335. The voltage source VCC2 is connected to the drain 36d of the fourth transistor TN335 and the drain 34d of the third transistor TN334, as well as to both of the gates 34g, 36g. The source 36s of the fourth transistor TN335 is connected to the drain 32d of the second mirror transistor TN333. Those having ordinary skill in the art will recognize the functionality and operational principles of this variation of the basic Wilson current mirror thus described, and so further details thereof will be omitted.

In the second embodiment of the bias boosting circuit 26b, the contemplated modified Wilson current mirror circuit that incorporates the first resistor R0, the second resistor R1, the third resistor R2, and the fourth resistor R3. The first resistor R0 is connected to the source 34s of the third transistor TN334, while the second resistor R1 is connected to the drain 30d of the first mirror transistor TN332. The first resistor R0 and the second resistor R1 are connected to each other and define a common node 28 at their junction. The third resistor R2 is connected to the source 34s of the third transistor TN334 and the gates 30g, 32g of the first and second mirror transistors TN332, TN333, respectively. The fourth resistor R3 is connected to the source 36s of the fourth transistor TN335 and the drain 32d of the second mirror transistor TN333. The operation of the second embodiment of the bias boosting circuit 26b is understood to be substantially the same as the first embodiment 26a, in that the bias boosting circuit 26b, in combination with the bias control resistor R4, biases the first power amplifier transistor TN330.

The graph of FIG. 4 plots a simulated gain curve of the power amplifier circuit 10 in accordance with various embodiments of the present disclosure. The gain curve is shown as a function of output power (in dBm), at an operating frequency of 698 MHz. Specifically, a first plot 38 shows the gain curve for the power amplifier circuit 10 that is biased with the bias boosting circuit 26a,b, while a second plot 40 shows the gain curve of the same power amplifier circuit 10 that is biased with a simple current mirror circuit with a 1 kΩ isolation resistor. For both of these simulations, the amplifiers are biased with the same quiescent current. As shown, the P1 dB point is extended by approximately 2.5 dB.

The graph of FIG. 4 illustrates the phase distortion (AM-PM) characteristics of the power amplifier circuit 10. A first plot 42 corresponds to the power amplifier circuit 10 biased with the bias boosting circuit 26 in accordance with various embodiments of the present disclosure, and a second plot 44 corresponds to the power amplifier circuit 10 biased with the aforementioned simple current mirror circuit. Both the first plot 42 and the second plot 44 show phase distortion in degrees as a function of output power (in dBm), at an operating frequency of 698 MHz. It is understood that phase distortion increases slightly in the power amplifier circuit 10 that is biased with the bias boosting circuit 26a,b. Phase distortion may be increased slightly, however, with reduced gain compression and increased output power, for better linearity and efficiency of the power amplifier circuit 10.

The particulars shown herein are by way of example and for purposes of illustrative discussion of the embodiments of the modified Wilson current mirror circuit only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A radio frequency (RF) power amplifier circuit including an input receptive to a signal, and an output, comprising:
an input matching network connected to the input;
an output matching network connected to the output;
a power amplifier with a power amplifier input connected to the input matching network and a power amplifier output connected to the output matching network; and
a bias boosting circuit connected to the power amplifier input, the bias boosting circuit comprising a modified Wilson current mirror with a pair of first and second mirror transistors connected to a third transistor, the first mirror transistor being configured for operating in a saturation mode and a gate voltage of the first mirror transistor being lower than a gate voltage of the power amplifier;
wherein the third transistor charges the power amplifier circuit during a positive half cycle of the signal and the first mirror transistor discharges the power amplifier circuit during a negative half cycle of the signal at different rates.

2. The RF power amplifier circuit of claim 1, wherein the power amplifier has a stacked transistor configuration including a first power amplifier transistor and a second power amplifier transistor, a gate of the first power amplifier transistor being connected to the input matching network, a drain of the second power amplifier transistor being connected to the output matching network, and a drain of the first power amplifier transistor being connected to a source of the second power amplifier transistor.

3. The RF power amplifier circuit of claim 1, wherein the modified Wilson current mirror includes a first resistor connected to a source of the third transistor and a second resistor connected to a drain of the first mirror transistor, the first resistor and the second resistor being connected at a common node.

4. The RF power amplifier circuit of claim 3, wherein the modified Wilson current mirror includes a third resistor connected to the source of the third transistor, and respective gates of the first and second mirror transistors.

5. The RF power amplifier circuit of claim 4, wherein the modified Wilson current mirror includes a fourth resistor connected to a gate of the third transistor and a drain of the second mirror transistor.

6. The RF power amplifier circuit of claim 3, further comprising:
a bias control resistor connected between the common node and the power amplifier, a value of the bias control resistor defining a bias boost level to the power amplifier.

7. The RF power amplifier circuit of claim 3, further comprising:
a capacitor connected in parallel with the first resistor and the second resistor to control charging and discharging rates.

8. The RF power amplifier circuit of claim 1, wherein the third transistor of the modified Wilson current mirror is connected to a voltage source.

9. The RF power amplifier circuit of claim 1, wherein the modified Wilson current mirror includes a fourth transistor connected to the second mirror transistor and the third transistor.

10. The RF power amplifier circuit of claim 9, wherein a gate of the third transistor and a gate of the fourth transistor are each connected to a current source.

11. The RF power amplifier circuit of claim 10, wherein the modified Wilson current mirror includes a first resistor connected to a source of the third transistor and a second resistor connected to a drain of the first mirror transistor, the first resistor and the second resistor being connected at a common node.

12. The RF power amplifier circuit of claim 11, wherein the modified Wilson current mirror includes a third resistor connected to the source of the third transistor, and respective gates of the first and second mirror transistors.

13. The RF power amplifier circuit of claim 12, wherein the modified Wilson current mirror includes a third resistor connected to the drain of the second mirror transistor and the source of the fourth transistor.

14. The RF power amplifier circuit of claim 9, further comprising:
a bias control resistor connected between the common node and the power amplifier, a value of the bias control resistor defining a bias boost level to the power amplifier.

15. The RF power amplifier circuit of claim 9, further comprising:
a capacitor connected in parallel with the first resistor and the second resistor to control charging and discharging rates.

16. A current mirror circuit for biasing a power amplifier, comprising:
a modified Wilson current mirror with a pair of first and second mirror transistors connected to a third transistor, the first mirror transistor being configured for operating in a saturation mode with a gate voltage of the first mirror transistor being lower than a gate voltage of the power amplifier;
wherein the third transistor charges the power amplifier circuit during a positive half cycle of an input signal and the first mirror transistor discharges the power amplifier circuit during a negative half cycle of the input signal at different rates.

17. The RF power amplifier circuit of claim 1, wherein the modified Wilson current mirror includes a fourth transistor connected to the second mirror transistor and the third transistor.

18. A modified Wilson current mirror circuit for biasing a power amplifier, comprising:
a pair of first and second mirror transistors each with a gate, a drain, and a source, the gate of the first mirror transistor being connected to the gate of the second mirror transistor;
a third transistor with a gate, a drain, and a source;
a first resistor connected to the source of the third transistor;
a second resistor connected to the drain of the first mirror transistor and the first resistor, a common node being defined at a junction between the first resistor and the second resistor;
a third resistor connected to the source of the third transistor and the gates of both the first and second mirror transistors; and
a bias boost control resistor connected to the common node and connectible to the power amplifier.

19. The modified Wilson current mirror circuit of claim 18, further comprising:
a current source input connected to the drain of the third transistor and the drain of the second mirror transistor.

20. The modified Wilson current mirror circuit of claim 18, further comprising:
a fourth resistor;
a fourth transistor with a gate, a drain and a source, the gate of the fourth transistor being connected to the gate of the third transistor, the drain of the fourth transistor being connected to the drain of the third transistor, and the source of the fourth transistor being connected to the drain of the second mirror transistor through the fourth resistor.
